(19) United States
(12) Patent Application Publication
(10) Pub. No.: US 2022/0111489 A1
(43) Pub. Date: Apr. 14, 2022

(54) POLISHING AGENT REGENERATING METHOD AND POLISHING AGENT RECYCLE PROCESSING SYSTEM

(71) Applicant: Konica Minolta, Inc., Tokyo (JP)

(72) Inventors: Keisuke MIZOGUCHI, Hachioji-shi, Tokyo (JP); Jing XUE, Hachioji-shi, Tokyo (JP); Fumiko TSUKIGATA, Hino-shi, Tokyo (JP); Akihiro MAEZAWA, Hino-shi, Tokyo (JP)

(21) Appl. No.: 17/420,621

(22) PCT Filed: Dec. 24, 2019
(86) PCT No.: PCT/JP2019/050487

§ 371 Date: Jul. 2, 2021

(30) Foreign Application Priority Data
Jan. 10, 2019 (JP) 2019-002337

(51) Int. Cl. B24B 57/02; C09G 1/04; B01D 21/24

(52) U.S. Cl. CPC B24B 57/02; B01D 21/01; B01D 21/2444; C09G 1/04

(57) ABSTRACT

A polishing agent regenerating method in which a component of a polished material is removed from polishing agent slurry and a polishing agent is collected and regenerated is shown. The method includes at least, polishing, polishing agent slurry supplying, polishing agent slurry collecting, and sedimenting/separating/concentrating, performed in the above order. In the polishing agent slurry collecting or the sedimenting/separating/concentrating, a K₂O density in the polishing agent slurry after dilution by water is performed is to be within a range of 0.002-0.2 mass %.

### TECHNICAL FIELD

The present invention relates to a polishing agent regenerating method and a polishing agent recycle processing system. More specifically, the present invention relates to a polishing agent regenerating method and a polishing agent recycle processing system which is used for polishing chemically strengthened glass, which efficiently removes glass components including K₂O from treated polishing agent slurry, which efficiently separates polished material, which provides stability in polishing speed, and which prevents decrease in quality due to scratches in the polishing material.

### BACKGROUND ART

At present, as a polishing agent for precise polishing in a finishing process in manufacturing of optical glass and a crystal oscillator, fine particles with high hardness are conventionally used, representative examples including, diamond, boron nitride, silicon carbide, alumina, alumina zirconia, zirconium oxide, and cerium oxide.

Such polishing agents include fine particles with high hardness. Therefore, these are important resources used heavily as an optical polishing agent for electronic components such as an optical lens, semiconductor silicon substrate, or glass plate of a liquid crystal display. Therefore, such polishing agents are one of the resources in which there is a strong demand for reuse. The polishing agent for optical polishing often include fine particles of rare earth elements. Therefore, there are serious problems to be dealt with such as development of techniques to reuse the resources or to make the waste pollution free.

Normally, when a large amount of such polishing agent is used in a polishing step, such waste liquid includes a comprising component of the polished material, such as optical glass scrap. However, normally it is difficult to efficiently separate the polishing agent and the polished material. Therefore, as described above, in most cases, the polishing agent waste liquid is disposed after use at present. This is a problem in view of the burden to the environment, effective use of resources, and cost of disposal.

Lately, with the drastic speed of spread of smartphones, the amount of production of display glass for smartphones is drastically increasing. Moreover, lately, the screens of smartphones are getting larger, and the area of a display glass (cover glass) to be used is becoming larger.

However, as the smartphone itself becomes larger by the screen becoming larger, there is a problem that the original portability and operability are lost. Since the display glass for smartphones easily break due to shock when dropped, in most cases, chemically strengthened glass is used.

Lately, in order to realize a large screen while maintaining compactness of the smartphone itself, a glass called 3D glass in which the edge is treated to be curved so that the edge of the screen can be used as the display screen is developed. Compared to conventional glass, the amount to be polished increases in such 3D glass due to the increased area, and the demand for regenerated polishing agent used in polishing is becoming higher.

However, with the increase in the polishing amount, the glass component amount in the polishing agent slurry used in circulation is also increasing. As the number of times of regeneration of the polishing agent increases, the quality of collected polishing agent slurry decreases.

In view of the above problems, the following is disclosed, a regenerating method of a polishing agent component in which polished polishing agent components are separated from a used polishing agent slurry of the polishing agent including cerium oxide by using magnesium salt, etc. (for example, Patent Literature 1).

However, in the polishing method performed lately, the amount of glass polishing scrap (hereinafter simply referred to as polishing scrap) included in the polishing agent slurry used in circulation and generated by polishing increases with the increase of the polishing amount. When the number of times of regeneration of the polishing agent increases according to such polishing method of the display glass for smartphones, there may be cases in which the polishing scrap such as glass and the polishing agent cannot be separated efficiently in such collected polishing agent slurry prepared with the regenerating method of the polishing agent component disclosed in the Patent Literature 1.

In order to cope with this problem, as a result of considering the reason, in cases where separation does not go well, it was found that a large amount of potassium components was found in the collected polishing agent slurry used for polishing the display glass for smartphones. This is because, the glass of the display glass for smartphones often breaks due to the shock of dropping, and chemically strengthened glass is used to cope with this problem. However, the edge is treated with a curved surface as 3D glass. Therefore, the impact stress when dropped concentrates at the edge. With this, the frequency of breaking increases. Therefore, as the applied glass, there is a demand for a chemically strengthened glass including a large amount of a chemically strengthening component (K₂O) compared to conventional glass. Such chemically strengthening component (K₂O) apply an influence to the separating and regenerating step of the polishing agent slurry, and reduces the production stability.

According to the regenerating method of the collected polishing agent slurry used in polishing the glass as disclosed in the Patent Literature 1, after the magnesium salt is added, the separating of the polishing agent and the polishing scrap generated in polishing are separated by adjusting the pH of the slurry solution. If the number of times of regenerating increases in such regenerating of the polishing agent slurry used in polishing of chemically strengthened glass with a large amount of K₂O component as described above, the sedimentation separation becomes difficult even if the pH is adjusted, and when the regenerating is performed a certain number of times or more, the slurry becomes flocked when the sedimenting/separating agent is added.

### CITATION LIST

### Patent Literature

Patent Literature 1: JP 5370598 B2

### SUMMARY

### Technical Problem

The present invention is made in view of the above problems and the problem to be solved by the present invention is to provide a polishing agent regenerating method and polishing agent recycle processing system which is used for polishing chemically strengthened glass, which efficiently removes glass components including K₂O from treated polishing agent slurry, which provides stability in polishing speed, and which prevents decrease in quality due to scratches generated by polishing scrap, etc.

### Solution to Problem

In the process of considering the reason to the problem in order to solve the problem, the inventors found a regenerating method of a polishing agent to remove the components of the polishing scrap from the polishing agent slurry used in polishing and to collect and regenerate the polishing agent. The method includes a polishing treating step, a polishing agent slurry supplying step, a polishing agent collecting step and a sedimenting/separating/concentrating step performed in the above order. In the above polishing agent slurry collecting step or the sedimenting/separating/concentrating step, the K₂O density in the polishing agent slurry after performing dilution by water is to be within a range of 0.002-0.2 mass %. With this, it is possible to achieve efficient separation of the glass component, to maintain polishing speed, and to prevent decrease in quality due to scratches in the polishing material.

That is, the problems regarding the present invention can be solved by the following.

1. A polishing agent regenerating method in which a component of a polished material is removed from polishing agent slurry and a polishing agent is collected and regenerated, the method including:

at least, polishing, polishing agent slurry supplying, polishing agent slurry collecting, and sedimenting/separating/concentrating, performed in the above order,

wherein, in the polishing agent slurry collecting or the sedimenting/separating/concentrating, a K₂O density in the polishing agent slurry after dilution by water is performed is to be within a range of 0.002-0.2 mass %.

2. The polishing agent regenerating method according to claim 1, wherein, in the polishing agent slurry collecting or the sedimenting/separating/concentrating, a K₂O density in the polishing agent slurry after dilution by water is to be within a range of 0.01-0.05 mass %.

3. The polishing agent regenerating method according to claim 1 or 2, wherein, in the polishing agent slurry supplying, the polishing agent slurry with a K₂O density within a range of 0.1-1.0 mass % is used.

4. The polishing agent regenerating method according to any one of claims 1 to 3, further comprising specific gravity adjusting in which specific gravity of the polishing agent slurry after the sedimenting/separating/concentrating is matched to specific gravity of the polishing agent slurry before adding water in the polishing agent slurry supplying.

5. The polishing agent regenerating method according to claim 4, further comprising adjusting a particle size of the polishing agent after the specific gravity adjusting.

6. The polishing agent regenerating method according to any one of claims 1 to 5, further comprising, between the polishing and the sedimenting/separating/concentrating, a K₂O density measurer which automatically measures the K₂O density in the polishing agent slurry and a water adder which automatically adds an added amount of water for dilution according to the obtained K₂O density information.

7. The polishing agent regenerating method according to any one of claims 1 to 6, wherein, the polished material is chemically strengthened glass.

8. A polishing agent recycle processing system in which a component of a polished material is removed from polishing agent slurry and a polishing agent is collected and regenerated, the system including:

a polisher;

a polishing agent slurry supplier which includes a slurry supply tank which supplies the polishing agent slurry to the polisher;

a polishing agent slurry collector which includes a collected mixed liquid tank in which mixed liquid including treated polishing agent slurry and washing water are mixed is stored;

a sedimentor/separator/concentrator which includes a separating tank which separates the mixed liquid to a transparent liquid and a concentrated liquid of the polishing agent; and

a water adder in which in the polishing agent slurry collector or the sedimentor/separator/concentrator, a K₂O density in the polishing agent slurry after dilution by water is to be within a range of 0.002-0.2 mass %.

9. The polishing agent recycle processing system according to claim 8, wherein, in the water adder, a K₂O density in the polishing agent slurry after dilution by water is to be within a range of 0.01-0.05 mass %.

10. The polishing agent recycle processing system according to claim 8 or 9, wherein, in the polishing agent slurry supplier, the polishing agent slurry with a K₂O density within a range of 0.1-1.0 mass % is used.

11. The polishing agent recycle processing system according to any one of claims 8 to 10, further comprising a specific gravity adjuster in which specific gravity of the polishing agent slurry after the sedimenting/separating/concentrating is matched to specific gravity of the polishing agent slurry before adding water in the polishing agent slurry supplying.

12. The polishing agent recycle processing system according to claim 11, further comprising an adjustor which adjusts a particle size of the polishing agent obtained by the specific gravity adjuster.

13. The polishing agent recycle processing system according to any one of claims 8 to 12, further comprising, between the polisher and the sedimentor/separator/concentrator, a K₂O density measurer which automatically measures the K₂O density in the polishing agent slurry and a water adder which automatically adds an added amount of water for dilution according to the obtained K₂O density information.

### Advantageous Effects of Invention

According to the above-described method of the present invention, it is possible to provide a polishing agent regenerating method and polishing agent recycle processing system which is used for polishing chemically strengthened glass. According to the above, glass components generated due to chemically strengthened glass is efficiently removed from treated polishing agent slurry. Further, according to the above, the polishing speed is maintained, and decrease in quality due to scratches made by the polishing scrap, etc. is prevented.

The mechanism of such effect of the present invention occurring or being produced is not clear, but the following is assumed.

In the glass polishing method, a SiO₂ density in the slurry supplying step is measured, and it is selected whether to perform the polishing agent regenerating process based on the measured result. Lately, in the polishing method of chemically strengthened glass (display glass, etc. for smartphone), the separation between the polishing agent and the polishing scrap cannot be performed well by only the conventional method of regenerating the polishing agent slurry using the SiO₂ density as the reference. As a result of consideration, it is assumed that it is necessary to define the K₂O density due to the chemically strengthened glass and to define a life end.

Conventionally, in the regenerating method of the glass polishing agent slurry, by adjusting the pH of the slurry solution, the polishing agent is separated from the polishing scrap which is a glass component. However, when the glass polishing agent slurry including the polishing scrap with a large amount of K₂O component generated in polishing is regenerated, when the number of times of regenerating increases, even if the pH is adjusted, the sedimenting and separating of the above becomes difficult, and when the regenerating is performed a certain number of times or more, the slurry becomes a flocked state when the sedimenting/separating agent is added.

As a result of consideration of the above problem, the present inventors conceived that it is necessary to reduce the included amount of K₂O, generated due to the chemically strengthened glass, in the collected polishing agent slurry in order to stably perform the separation between the polishing agent and the polishing scrap which is the chemically strengthened glass component. Specifically, the present inventors found that by diluting the K₂O density in the collected polishing agent slurry within the range of 0.002-0.2 mass %, the above can be separated stably even if the number of times of regenerating increases.

According to the regenerating method of the polishing agent, the system is established so that the K₂O density is measured and the dilution is performed automatically according to the measured density. With this, the regenerating of the polishing agent slurry can be performed automatically.

### BRIEF DESCRIPTION OF DRAWINGS

FIG. 1 is a schematic diagram showing an example of a flow of processes performed in a regenerating method of a polishing agent according to the present invention.

### DESCRIPTION OF EMBODIMENTS

A polishing agent regenerating method according to the present invention includes, polishing, polishing agent slurry supplying, polishing agent slurry collecting, and sedimenting/separating/concentrating, and in the polishing agent slurry collecting or the sedimenting/separating/concentrating, a K₂O density in the polishing agent slurry after dilution by water is performed is to be within a range of 0.002-0.2 mass %. The above is the technical feature common to or corresponding to the embodiments described below.

Preferably, according to an embodiment of the present invention, from the viewpoint of enhancing the effect which is the purpose of the present invention, in the polishing agent slurry collecting or the sedimenting/separating/concentrating, a K₂O density in the polishing agent slurry after dilution by water is to be within a range of 0.01-0.05 mass %. With this, the polishing agent and the polishing scrap which is a chemically strengthened glass component can be separated more efficiently.

Preferably, in the polishing agent slurry supplying, the polishing agent slurry with a K₂O density within a range of 0.1-1.0 mass % is used. With this, the polishing agent and the polishing scrap which is a chemically strengthened glass component can be separated more efficiently.

Preferably, further including specific gravity adjusting in which specific gravity of the polishing agent slurry after the sedimenting/separating/concentrating is adjusted to specific gravity of the polishing agent slurry before adding water in the polishing agent slurry supplying enables the regenerating of the polishing agent to be performed more efficiently.

Preferably, further including adjusting a particle size after the specific gravity adjusting (hereinafter also called particle size adjusting) enables the polishing agent slurry including the polishing agent particle with a narrow particle size distribution to be obtained.

Preferably, between the polishing and the sedimenting/separating/concentrating, further including a K₂O density measurer which automatically measures the K₂O density in the polishing agent slurry and a water adder which automatically adds an added amount of water for dilution according to the obtained K₂O density information enables the regenerating method of the polishing agent in which the regenerating of the polishing agent slurry to be automated.

A polishing agent recycle processing system including: a polisher in which the polishing device is used to perform polishing; a polishing agent slurry supplier which includes a slurry supply tank which supplies the polishing agent slurry to the polisher; a polishing agent slurry collector which includes a collected mixed liquid tank in which mixed liquid including treated polishing agent slurry and washing water are mixed is stored; a sedimentor/separator/concentrator which includes a separating tank which separates the mixed liquid to a transparent liquid and a concentrated liquid of the polishing agent; and a water adder in which in the polishing agent slurry collector or the sedimentor/separator/concentrator, a K₂O density in the polishing agent slurry after dilution by water is to be within a range of 0.002-0.2 mass %.

The present invention, the components of the present invention, and the embodiment to implement the present invention are described in detail. According to the present invention “-” is used as the meaning that the values described before and after are included as a minimum value and a maximum value.

According to the present invention, polishing agent slurry is slurry expressed collectively including various types of polishing agent slurry according to the polishing treating step.

<<Regenerating Method of Polishing Agent>>

A regenerating method of a polishing agent according to the present invention is the regenerating method of the polishing agent in which components of a polished material are removed from a polishing agent slurry used for polishing of a polishing material and the polishing agent is collected and regenerated. The method includes at least a polishing treating step, a polishing agent slurry supplying step, a polishing agent slurry collecting step and a sedimenting/separating/concentrating step performed in the above order. A K₂O density in the polishing agent slurry after dilution by water is performed in the polishing agent slurry collecting step or the sedimenting/separating/concentrating step is to be within a range of 0.002-0.2 mass %.

[Basic Steps in Regenerating Method of Polishing Agent]

As the steps applied to the regenerating method of the polishing agent according to the present invention, the polishing treating step, the polishing agent slurry supplying step, the polishing agent slurry collecting step, and the sedimenting/separating/concentrating step are included in this order. Further, preferably, after the sedimenting/separating/concentrating step, a specific gravity adjusting step which adjusts specific gravity of a polishing agent slurry to a specific gravity of a polishing agent slurry before adding water in the polishing agent slurry supplying step, and a polishing agent particle size adjusting step which adjusts a particle size of the polishing agent obtained in the specific gravity adjusting step are included. Preferably, a K₂O density measurer which automatically measures the K₂O density in the polishing agent slurry between the polishing treating step and the sedimenting/separating/concentrating step and a water adder which automatically adds an added amount of water for dilution according to the obtained K₂O density information are included.

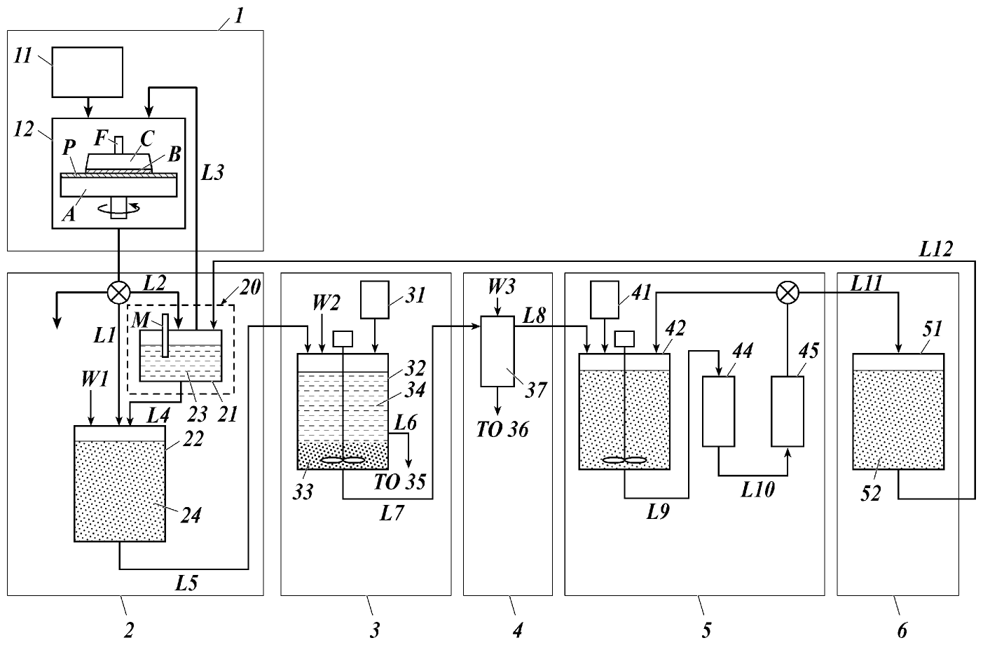

FIG. 1 is a schematic diagram showing an example of a flow of a regenerating step of a polishing agent in which the regenerating method of the polishing agent according to the present invention can be applied.

The regenerating method shown in FIG. 1 shows the following steps in order, a polishing treating step 1, a polishing agent slurry collecting step 2 including polishing agent slurry supplying step 20, a sedimenting/separating/concentrating step 3, a specific gravity adjusting step 4, a polishing agent particle size adjusting step 5, and a regenerating polishing agent slurry preparating step 6. Each of the above steps are connected by pipes L1-L12.

[Processing Method of K₂O Component]

The detailed configuration of the regenerating method of the polishing agent according to the present invention and the polishing agent recycle processing system according to the present invention are described with reference to FIG. 1.

As shown in FIG. 1, the feature of the present invention is a method in which in the polishing agent slurry supplying step 20, after the K₂O density in a polishing agent slurry 23 stored in a slurry supply tank 21 is measured with an ion meter M, according to the measured K₂O density information, dilution water W1-W2 is added to the polishing agent slurry in the collected mixed liquid tank 22 and a separating/concentrating tank 32, and then the dilution water including K₂O is discharged outside the system to reduce the K₂O amount in the collected polishing agent slurry. According to the present invention, the feature is that the K₂O density in the polishing agent slurry after the step performing the dilution by water in the polishing agent slurry collecting step 2 or the sedimenting/separating/concentrating step 3 is within a range of 0.002-0.2 mass %. The K₂O density is measured by a method similar to the above.

According to the present invention, the dilution is performed so that the K₂O density in the polishing agent slurry is to be within the range of 0.002-0.2 mass %. The amount of water added for dilution (dilution magnification) to the collected polishing agent slurry is not limited as long as the above defined K₂O density can be obtained. Considering polishing abilities and the size of an adjusting container, etc. included in the regenerating step of the polishing agent, the dilution magnification is within the range of 5-100 times, more preferably, 5-50 times.

First, the polishing agent slurry which is generated in the polishing treating step 1 and used in polishing is collected in the slurry supply tank 21 positioned in the polishing agent slurry supplying step 20 through a pipe L2. Further, the new regenerated polishing agent slurry is added from a regenerated polishing agent slurry storage tank 51 through a pipe L12.

Specifically, the density of K₂O generated in the polishing step of a chemically strengthened glass is measured for the polishing agent slurry 23 in the slurry supply tank 21 according to the above configuration by using an ion meter M.

The method to measure the K₂O density which can be applied to the present invention includes performing measurement by combining, for example, a potassium ion electrode “8202-10C” and a desktop ion meter “F74” (the above manufactured by HORIBA, Ltd.) and converting the result to the K₂O density so as to obtain the K₂O density. As other methods, it is possible to obtain the K₂O density by measurement using a compact potassium meter “LAQUAtwin K114” (manufactured by HORIBA, Ltd.) or an online ion chromatography device (NIKKISO, CO. LTD.).

When the K₂O density in the polishing agent slurry 23 stored in the slurry supply tank 21 is measured by the ion meter M and the K₂O density is determined to be within the range of 0.05-1.0 mass %, the desired dilution water W1 is added to the polishing agent slurry 23 in the collected mixed tank 22 storing the polishing agent slurry 23 of the polishing agent slurry collecting step 2 so that the dilution water W1 is added to the polishing agent slurry 23, and the K₂O density in the polishing agent slurry 23 is to be within the range of 0.002-0.2 mass %.

According to the present invention, the method of adding the dilution water W2 to the polishing agent slurry 23 can be to add a predetermined amount of the dilution water W2 to the separating/concentrating tank 32 included in the sedimenting/separating/concentrating step 3.

An inorganic salt, for example, alkaline earth metal salt is added from an additive tank 31 to the polishing agent slurry 23 already prepared and diluted according to the above method and only the polishing agent component is aggregated and precipitated to be a precipitate 33. The chemically strengthened glass scrap which is polished scrap from the polished material (glass component) is separated as supernant liquid 34 in a state which is not aggregated. A predetermined amount of the supernant liquid 34 is discharged 35 outside the system through the pipe L6. With this, the K₂O component and the unnecessary salts can be removed.

[Details of Each Step Applied to Regenerating Method of Polishing Agent]

Next, each step (also called units) regarding the regenerating method of the polishing agent and the recycle processing system of the polishing agent according to the present invention is described in detail.

(1) Polishing Treating Step

The polishing treating step 1 includes a polishing apparatus 12, and the polished material, for example, the chemically strengthened glass is polished by the polishing agent.

As shown in the polishing treating step 1 in FIG. 1, the configuration of the polisher 12 includes a polishing surface plate A in which a polishing cloth P which is a polishing cloth made of suede is attached. The polishing surface plate A can be rotated. When polishing is performed, the polished material B (hereinafter referred to as chemically strengthened glass substrate or simply glass substrate) held by a polished material holder C is pressed to the polishing surface plate A at a pressure force F, and the polishing surface plate A is rotated at a certain speed. Next, through the pipe L3, the polishing agent slurry 23 at 25° C. stored in the slurry supply tank 21 is supplied to the polishing cloth P. The polishing agent slurry 11 after polishing is sent to the slurry supply tank 21 again through the pipe L2, and the operation is repeatedly performed. Washing water to wash the polisher 12 is stored in a washing water tank 11, and the washing water is sprayed to the polisher by a washing water jet nozzle and washing is performed.

(Polished Material: Chemically Strengthened Glass) The regenerating method of the polishing agent according to the present invention achieves excellent effects when applied to the polishing method using the chemically strengthened glass as the polished material B.

The chemically strengthened glass according to the present invention is glass in which the surface of the glass is strengthened using a chemical process such as an ion exchange method. The ion exchange method is a method in which a float glass plate including a Na component or a Li component such as soda lime silicate glass is immersed in molten salt such as potassium nitrate, and Na ion and/or Li ion which exist on a surface of the glass plate and which have a small atomic size are exchanged with K ion which exist in molten salt and which have a large atomic size. As a result, a compressive stress layer is formed on a surface layer of the glass plate and with this, a glass plate with the strength enhanced can be obtained. Chemically strengthened glass which are available on the market include chemically strengthened glass manufactured by Corning Japan or Nippon Sheet Glass, Co. Ltd.

The thickness of the chemically strengthened glass differs depending on the purpose of use, but is within the range of about 0.4-10.0 mm.

(Polishing Agent)

Typically, as the component of the polishing agent for polishing optical glass or a semiconductor substrate, a slurry type is used in which fine particles such as red iron oxide (αFe₂O₃), cerium oxide, aluminum oxide, manganese oxide, zirconium oxide, colloidal silica and the like are dispersed in water or oil. According to the polishing agent regenerating method of the present invention, in the polishing treatment of the surface of the semiconductor substrate and polishing treatment of the glass, in order to maintain flatness at a high accuracy while obtaining sufficient treatment speed, it is preferable to apply the present invention to the collecting of at least one type selected from the following, diamond, boron nitride, silicon carbide, alumina, alumina zirconia, zirconium oxide and cerium oxide. The above can be applied to chemical mechanical polishing (CMP) in which polishing is performed as both a physical effect and a chemical effect.

As the constituent component of the polishing agent according to the present invention, as a diamond type, there are, for example, synthetic diamond (for example, Japan Micro-coating, etc.), or natural diamond, and as a boron nitride type, there is, for example, cubic boron nitride BN (for example, Showa Denko). The boron nitride type has a hardness second to the diamond. As the silicon carbide type, there are silicon carbide, green silicon carbide, black silicon carbide (for example, Mipox, etc.) and the like. As the alumina type, in addition to alumina, there are, brown alumina, white alumina, light pink alumina, monocrystalline fused alumina, alumina zirconia type (for example, Saint-Gobain) and the like. As zirconium oxide, there are, for example, BR series zirconium oxide for polishing by Daiichi Kigenso Kagaku Kogyo or zirconium oxide by China HZ.

As for cerium oxide (for example, C.I. formation, Techno Rise, Wako Pure Medicine, etc.), instead of pure cerium oxide, a type called bastnasite in which ore including plenty of rare earth elements is burned, and then crushed is often used. Cerium oxide is the main component, but rare earth elements such as lanthanum, neodymium, and praseodymium are also included. Other than oxides, fluoride, etc. may also be included.

Regarding the polishing agent used in the present invention, those with a contained amount of the constituent component of the polishing agent being 50 mass % or more are effective and preferable. More preferably, the range is within 95-100 mass %, and even more preferably, 100 mass %.

The polishing treatment method of the glass substrate as shown in FIG. 1 is described in more detail.

In the polishing treating step 1, a polishing treatment unit including the polisher 12 and a cleaning unit of the polisher including the washing water tank 11 are included in one polishing treating step.

(1-1) Polishing

The polishing pad P (polishing cloth) and the polished material B (for example, chemically strengthened glass substrate) come into contact, and while supplying polishing agent slurry to a contact surface, the polishing pad P and the glass substrate are moved relatively under pressured conditions.

After continuous polishing, pad dressing or pad brushing can be performed on the polishing pad P. Pad dressing is a process in which the pad is physically shaved and the surface is made rough so that the state of the pad is maintained in a certain state. Pad brushing is a process in which the pad is not shaved and polishing scraps included in the bumps and dents in the pad are removed.

Polishing can be performed by using a plurality of polishers for one batch of treatment. In this case, preferably, the range of the change in the treatment time for each batch is equal to or less than 10% from the previous batch to the next batch. If it is within this range, the variation in the treatment time for polishing among the plurality of polishing terms can be suppressed. Here, one batch is a unit of one polishing process, and the polishing process of six glass substrates can be performed in one batch, for example.

(1-2) Washing

Right after the polishing, a great amount of polishing agent is attached to the glass substrate B and the polisher 12. Therefore, after the polishing, instead of the polishing agent slurry, water from a washing tank 11 is supplied, and the washing of the polishing agent attached to the glass substrate and the polisher is performed.

(2) Polishing Agent Slurry Supplying Step

In the slurry supply tank 21 included in the polishing agent slurry supplying step 20, the treated polishing agent slurry discharged from the polisher 12 is collected through the pipe L2. The polishing agent slurry 23 in the slurry supply tank 21 is supplied to the polisher 12 through the pipe L3.

With the supply of the polishing agent slurry 23 to the polisher 12, in the polishing agent slurry supplying step 20, new regenerated polishing agent slurry is added to the slurry supply tank 21 from the regenerated polishing agent slurry storage tank 51 through the pipe L12. The method of adding the regenerated polishing agent slurry can be performed by adding the regenerated polishing agent slurry in every batch or by adding the regenerated polishing agent slurry in every few batches. Preferably, the polishing agent sufficiently dispersed in the solvent is supplied.

In the polishing agent slurry supplying step 20, an ion meter M which measures K₂O density in the polishing agent slurry 23 stored in the slurry supply tank 21 is provided.

(3) Polishing Agent Slurry Collecting Step

The polishing agent slurry collecting step shown with reference numeral 2 in FIG. 1 shows a configuration including the polishing agent slurry supplying step 20. In the polishing agent slurry collecting step 2, in addition to transmitting liquid to a collected mixed liquid tank 22 through the pipe L4 in order to regenerate the polishing agent slurry stored in the slurry supply tank 21, the treated polishing agent slurry and washing water discharged from the system including the polisher 12 and the washing water tank 11 is collected in the collected mixed liquid tank 22 through the pipe L1.

According to the present invention, the regenerated polishing agent slurry is supplied to the slurry supply tank 21 from the regenerated polishing agent slurry storage tank 51 while controlling the density of the components of the polishing agent in the slurry supply tank 21 to be equal to or less than the initial density when the polishing treating step starts.

The treated polishing agent slurry (hereinafter also referred to as polishing agent slurry A) according to the present invention is polishing agent slurry discharged outside the system through the pipe L1 by the polishing treating step 1 including the polisher 12 and the washing water tank 11.

After the polishing agent slurry including the treated polishing agent slurry A collected by the polishing treating step 1 and the polishing agent slurry supplied by the slurry supply tank 21 through the pipe IA (hereinafter also referred to as polishing agent slurry B) is collected in the collected mixed liquid tank 22, and after the polishing agent slurry is collected to a certain amount, according to the K₂O density information measured by the polishing agent slurry supplying step 20 according to the present invention, for example, a predetermined amount of dilution water W1 is added to achieve dilution of 5-50 times the initial polishing agent slurry mass, and the diluted polishing agent slurry 24 is prepared with the K₂O density within the range of 0.002-0.2 mass %. Preferably, the collected polishing agent slurry is always stirred to prevent aggregation and sedimentation of polishing agent particles and to maintain a stable dispersed state.

According to the present invention, the preparation of the diluted polishing agent slurry 24 with the K₂O density within the range of 0.002-0.2 mass % by adding the dilution water can be performed in the sedimenting/separating/concentrating step 3 which is the next step as shown in reference numeral 3 in FIG. 1.

(Adjustment of Density of Polishing Agent Slurry)

The adjustment of the density of the polishing agent slurry can be performed by controlling through the pipe L the flow amount of the water, regenerated polishing agent slurry, and treated polishing agent slurry A discharged from the polishing treating step which are provided to the slurry supply tank 21. The supply to the polisher 12 is performed from the slurry supply tank 21 using a pump (not shown) provided in the pipe L3 of the polisher 12. A controller includes a flowmeter and a pump, and the flow amount is controlled by a circulation line which supplies the polishing agent slurry throughout the procedure units and pipes which supply other additives.

(4) Sedimenting/Separating/Concentrating Step

According to the present invention, the diluted polishing agent slurry 24 which is diluted by the dilution water W1 prepared in the collected mixed liquid tank 22 and which is adjusted so that the K₂O density is within the range of 0.002-0.2 mass % is processed in the sedimenting/separating/concentrating step 3 which is the next step.

According to the present invention, the process of preparing the diluted polishing agent slurry by adding the dilution water can be performed in this sedimenting/separating/concentrating step 3 before performing the sedimenting/separating operation.

In the sedimenting/separating/concentrating step 3, after the diluted polishing agent slurry 24 collected in the polishing agent slurry collecting step 2 is transported through the pipe L5 to the separating/concentrating tank 32, an aggregating agent of the polishing agent such as alkaline earth metal salts are added from the additive tank 31 to the diluted polishing agent slurry 24. Sedimentation and separation of only the polishing agent particle is performed, and a glass component including K₂O and salts generated in the supernatant liquid by the polishing operation with the exception of the sedimentation are discharged outside the system. With this, the polishing agent and the glass component including K₂O are separated.

In the sedimenting/separating/concentrating step 3 according to the present invention, a well-known method can be used as the sedimenting/separating method. For example, the polishing agent slurry 24 is collected in the polishing agent slurry collecting step 2 and predetermined dilution water is added to prepare the diluted polishing agent slurry 24. The alkaline earth metal salts are added to the diluted polishing agent slurry 24 as inorganic salts. In a state in which only the polishing agent is aggregated and the glass components which is the polished component is not aggregated, the polishing agent is sedimented and separated from the mother liquid and is to be concentrate 33. With this, after only the polishing agent component is aggregated and sedimented, the glass component including K₂O mostly exists in the supernatant liquid 34. The above is the step in which it is possible to separate the polishing agent component from the glass component.

Well-known methods can be used as the method of sedimenting and separating. A film separating method or a sedimenting method can be employed.

Preferably, in order to perform sedimenting and separating, as described above, the polishing agent is separated from the mother liquid in a state in which alkaline earth metal salts are added as the inorganic salts, only the polishing agent is aggregated, and the glass component which is the polished component is not aggregated.

The operation of separating solid and liquid can be performed by spontaneous sedimentation without applying measures to force separation. Such mother liquid is separated to a supernatant liquid 34 including the polished material and the concentrate 33 including the collected polishing agent sedimented in the lower portion.

(Alkaline Earth Metal Salts)

According to the present invention, preferably, the inorganic salts used to aggregate the polishing agent is alkaline earth metal salts.

Examples of the alkaline earth metal salts which can be applied to the present invention include, calcium salts, strontium salts, and barium salts. Further, according to the present invention, the alkaline earth metal is defined in a broad sense, and elements belonging to group 2 in the periodic table are also included. Therefore, beryllium salts and magnesium salts are included in the alkaline earth metal salts according to the present invention.

Preferably, the alkaline earth metal salts which can be applied to the present invention are in the form of halide, sulfate, carbonate, acetate, or the like.

The preferable inorganic salt according to the present invention is alkaline earth metal salts, and more preferably, magnesium salts.

The magnesium salts which can be applied to the present invention is not limited as long as the function as an electrolyte is included. Since the solubility in the water is high, the following are preferable, magnesium chloride, magnesium bromide, magnesium iodide, magnesium sulfate, and magnesium acetate. Since the pH change in the solution is small and the process of the settled polishing agent and the waste liquid is easy, the following are especially preferable, magnesium chloride and magnesium sulfate.

(Method to Add Inorganic Salts)

Next, the method to add the inorganic salts in the polishing agent slurry (mother liquid) according to the present invention is described.

a) Density of Inorganic Salts

The inorganic salts to be added can be added by directly supplying a powder to the diluted polishing agent slurry 24. Alternatively, the inorganic salts can be added by first dissolving in a solvent such as water and then adding in the diluted polishing agent slurry 24. Preferably, the inorganic salts are added in a state dissolved in a solvent so that the state is even after being added to the diluted polishing agent slurry 24.

The preferable density of the inorganic salts is an aqueous solution with the density within the range of 0.5-50 mass %. Preferably, the density is within the range of 10-40 mass % to suppress the pH change in the system and to make the separation from the glass component efficient.

b) Adding Temperature of Inorganic Salts

The temperature at which the inorganic salt is added can be suitably selected in a range from a temperature equal to or higher than a temperature in which the collected polishing agent slurry freezes to up to 90° C. From the viewpoint of efficiently performing separation from the glass components, the preferable range is 10-40° C., and the more preferable range is 15-35° C.

c) Adding Speed of Inorganic Salts

Preferably, the speed of adding the inorganic salts to the diluted polishing agent slurry 24 is set to add the inorganic salts so that there is no high density region locally occurring and the density of the inorganic salts in the collected polishing agent slurry is even. Preferably, the added amount for each minute is equal to or less than 20 mass % of the entire added amount, and more preferably, the amount is 10 mass % or less.

d) pH Value when Inorganic Salts are Added

According to the polishing agent collecting/regenerating method of the present invention, when the inorganic salts are added in the sedimenting/separating/concentrating step 3, preferably, the pH value of the diluted polishing agent slurry 24 is not adjusted in advance. Typically, the pH value of the collected polishing agent slurry shows rather alkaline due to glass components being included. The range is 8 to less than 10, and the pH value of the collected polishing agent slurry does not have to be adjusted in advance. Therefore, according to the present invention, preferably, the separation and concentration are performed with the condition that the pH value in a 25° C. conversion of the diluted polishing agent slurry (24) is less than 10.0.

According to the present invention, the value measured using a desktop Lacombe tester pH meter (As One, pH1500) at 25° C. can be used as the pH value

According to the present invention, when the inorganic salts are added, it is preferable to maintain the pH value to a pH value equal to or less than when the inorganic salts are added until the concentrate is separated later. Here, the pH value when the inorganic salts are added is the pH value immediately after the adding of the inorganic salts ends.

The pH value is maintained to equal to or less than the pH value when the inorganic salts are added until the sedimented aggregate is separated. Preferably, less than 10 is maintained as the pH value at a 25° C. conversion. By maintaining less than 10 as the pH value, it is possible to prevent aggregation of the glass component included in the waste liquid. Therefore, it is possible to make the purity of the cerium oxide high when collected.

The minimum of the pH value when the inorganic salts are added is preferably equal to or more than 6.5 from the viewpoint of decrease in purity by pH adjustors and operability.

e) Stirring After Adding Inorganic Salts

After the inorganic salts are added, preferably, stirring is continued for at least 10 or more minutes, and more preferably, 30 or more minutes. The aggregation of the polishing agent particles start at the same time as the inorganic salts are added, but by maintaining a stirred state, the aggregated state becomes even in the entire system, the granularity distribution of the concentrate becomes narrow, and the separation later on becomes easier.

The separating/concentrating step 3 separates the supernatant liquid including glass components and concentrate including the collected polishing agent particles, and then collects the concentrate.

[Concentrating Step]

According to the regenerating method of the polishing agent of the present invention, in the sedimenting/separating/concentrating step 3, after the diluted polishing agent slurry 24 is separated to the supernatant liquid 34 and the concentrate 33, the concentration process in which the predetermined amount of the supernatant liquid including the glass component including K₂O is discharged outside the system is performed.

Here, with the concentration condition that the specific gravity of the polishing agent slurry is to be the same as the specific gravity before adding water according to the added amount of water in the polishing agent slurry collecting step or the sedimenting/separating/concentrating step, the concentrating operation by the waste liquid of the supernatant liquid 34 is performed.

The specific method may be as shown in the sedimenting/separating/concentrating step 3 shown in FIG. 1. After the diluted polishing agent slurry 24 is separated to the supernatant liquid 34 and the concentrate 33, a decantation method may be performed. For example, the supernatant liquid is discharged by tilting a pot. Alternatively, the following method may be performed, a method in which a liquid discharge pipe is inserted near an interface between the supernatant liquid 34 and the concentrate 33 separated in the pot, and only the supernatant liquid is discharged outside the pot through the pipe L6 to achieve concentration.

According to the present invention, from the view point of not mixing impurities (for example, polished glass coarse particles, etc.) as much as possible in the concentrate 33 sedimented in the bottom to obtain the regenerated polishing agent with high purity, preferably, spontaneous sedimentation is applied as a primary concentration method.

By adding the inorganic salts, the collected polishing agent particles are aggregated and the concentrate 33 is separated from the supernatant liquid 34 in this state. Therefore, the specific gravity of the concentrate 33 increases compared to the collected slurry and the concentrate 33 is concentrated. The collected polishing agent is included in the concentrate 33 at a density equal to or larger than the collected slurry.

The following are methods of operation to discharge the supernatant liquid 34.

1) The method of discharging the supernatant liquid 34 until the specific gravity of the polishing agent slurry including the concentrate 33 and the supernatant liquid 34 after discharge become the same as the polishing agent slurry 23 before adding water,

2) The method in which, after discharging the supernatant liquid 34 close to the limit and after discharging impurities (glass components, etc.), adding water so as to be the same specific gravity as the polishing agent slurry 23 before adding water.

(4) Specific Gravity Adjusting Step

The specific gravity adjusting step 4 is the method described in the above-described item 2). After the concentrate 33 is collected, as shown in reference numeral 4 in FIG. 1, for example, an ultrafiltration apparatus 37 including a membrane filter is used to discharge unnecessary salts included in the regenerated polishing slurry outside the system, and at the same time, while controlling the adding amount of the dilution water W3 and the discharge amount 36 from the ultrafiltration apparatus 37, the specific gravity of the polishing agent slurry after the sedimenting/separating step 3 is matched to the specific gravity of the polishing agent slurry 21 before adding water in the polishing agent slurry supplying step 20.

The specific gravity of the polishing agent slurry can be obtained by measurement at 25° C. using a commercially available specific gravity meter such as a vibrating density specific gravity meter by ADVANTEC CO., LTD., a portable density specific gravity meter by KYOTO ELECTRONICS MANUFACTURING CO., LTD.

(5) Polishing Agent Regenerating Step

(5-1) Polishing Agent Particle Size Adjusting Step

The polishing agent particle size adjusting step 5 is a step in which, after adding the various additives such as the dispersing agent from the additive tank 41 into the aggregated polishing agent, the polishing agent is dispersed again to a desired granularity distribution and the adjustment is made to be the granularity distribution level close to the polishing agent not yet used (before polishing). According to the present invention, preferably, the particle size control operation of the polishing agent particle is performed on the sedimented/separated/concentrated polishing agent slurry in which specific gravity is adjusted.

In the polishing agent slurry sedimented/separated and concentrated by the above method, the polishing agent particle forms an aggregated body (secondary particle) with the inorganic salts. In order to release to a state close to the independent primary particle, water and dispersing agent are added, and a dispersing device is used to disperse to the desired particle size.

The following methods are examples to disperse the aggregated polishing agent particles again. For example, a) method in which water is added to reduce inorganic ion density including an aggregating effect on the polishing agent in the processing liquid, b) method in which the dispersing agent is added (also called metal separating agent) to reduce the metal ion density attached to the polishing agent, and c) method in which a disperser is used to forcibly peptize the aggregated polishing agent particle.

These methods can be used alone or in combination, but preferably at least b) is combined in the method, and more preferably, all of the methods a), b), and c) are combined.

When water is added, the added amount is suitably selected by the volume of the concentrated polishing agent slurry. Typically, the amount is 5-50 volume % of the concentrated slurry, and preferably, the amount is 10-40 volume %.

(Dispersing Agent)

Well-known dispersing agents can be used as the dispersing agent. The added amount can be within the range of 0.01-5.0 g/L with relation to the regenerated polishing agent slurry.

According to the present invention, preferably, polycarboxylic acid polymer dispersing agent including carboxy group is used and specifically, this is an acrylic acid-maleic acid copolymer.

When the polishing treatment of the glass substrate continues, the pH of the polishing agent slurry during treatment becomes higher and shifts to the alkaline side with the dissolving of the polished material such as polysilicic acid. Shifting to the alkaline side easily causes damage such as decoloration (phenomenon of outer appearance of glass becoming gradually white and foggy) on the surface of the polished material. If acid to avoid damage is added to adjust the pH, the dissolved polysilicic acid easily becomes solid, and this decreases the non-defective rate of the polished material.

By using the acrylic acid-maleic acid copolymer as the dispersing agent, it is possible to decrease the occurrence of such phenomenon. In addition to the function as the dispersing agent, it is assumed that the equilibrium state of the hydrolysis in the maleic acid causes a buffer effect on the change in the pH of the polishing agent slurry during treatment, and the dissolved polysilicic acid does not become solid and stably maintains a dissolved state.

The maleic acid-acrylic acid copolymer includes a buffer effect on the pH change and is useful as an additive including a dispersion function. Not only is the above used as the dispersing agent in the polishing agent particle size adjusting step 5, but the above can also be used as an additive which is separately added to the slurry supply tank 21 or the regenerated polishing agent storage tank 51.

From the viewpoint of stably maintaining the pH value in the slurry supply tank 21, preferably, the regenerated polishing slurry in the regenerated polishing agent storage tank 51 in the regenerated polishing agent included liquid adjusting step 6 includes the maleic acid-acrylic acid copolymer in the range of 0.04-1.50 g/L.

Reference numeral 44 shown in reference numeral 5 in FIG. 1 is a dispersing device. For example, an ultrasound disperser, or a medium stirring type mill such as a sand mill or a beads mill can be applied. Preferably, the ultrasound disperser is used.

Various devices are commercially available as the ultrasound disperser from SMT, Ginsen, Taitec, BRANSON, Kinematica, Nihonseikikaisha, and the like. Devices such as UDU-1, UH-600MC by SMT, GSD600CVP by Ginsen, and RUS-600TCVP by Nihonseikikaisha can be used. The frequency of the ultrasound is not limited.

As a circulating type apparatus which performs both mechanical stirring and ultrasound dispersion at the same time, there are, UDU-1, UH-600MC by SMT, GSD600RCVP, GSD1200RCVP by Ginsen, and RUS-600TCVP by Nihonseikikaisha, but the apparatus is not limited to the above.

For example, water is added, and the polishing agent dispersed liquid in which the inorganic salt density is decreased is stored. Then, while stirring with a stirrer, the dispersing agent (such as polymer dispersing agent) is added with an adding container. Then, a pump is used, the dispersing process is performed in the ultrasound disperser 44, and the aggregated polishing agent particles are released. Then, in the particle size measuring device 45 provided on the downstream side, the particle size distribution of the polishing agent particle after dispersion is monitored, and the particle size distribution of the polishing agent dispersed liquid can be the desired particle size distribution profile.

Preferably, the granularity distribution obtained in this step has a small change over time in the particle size distribution, and the change in the average particle size after one day passes is small.

(5-2) Regenerated Polishing Agent Slurry Preparing Step

In the regenerated polishing agent slurry preparing step 6, the necessary additives are added in this way. The regenerated polishing agent slurry 52 prepared at a predetermined density is stored in the regenerated polishing agent slurry storage tank 51 and sent to the slurry supply tank 21 through the pipe L12.

According to the present invention, preferably, the final regenerated polishing agent slurry 52 obtained in the regenerated polishing agent slurry preparing step 6 includes the polishing agent at a high purity of 98 mass % or more, includes a small change over time in the granularity distribution, includes the density higher than at the time of recovery, and includes the inorganic salts to be an amount within a range of 0.0005-0.08 mass %.

As described above, the regenerated polishing agent with high quality and high purity can be obtained by an easy method as regenerated polishing agent slurry.

### EXAMPLE

The present invention is specifically described according to the following examples, but the present invention is not limited to the examples described below. In the description of the examples “%” is used but this represents “mass %” unless otherwise specified.

### Example 1

<<Preparation of Regenerated Polishing Agent>>

[Preparation of Regenerated Polishing Agent Slurry 1: Comparative Example]

According to the steps of the method for regenerating the polishing agent as shown in FIG. 1, the regenerated polishing agent slurry 1 is prepared.

1) Polishing Treating Step and Polishing Agent Slurry Collecting Step

According to the polishing treating step 1 shown in FIG. 1, the polisher 12 is used so that while the regenerated polishing agent slurry 23 including the polishing agent particles is supplied to a polishing target surface, the polishing target surface is polished with a polishing cloth P. The polishing treatment is performed by supplying the polishing agent slurry 23 at a flow amount of 5 L/min to circulate in the pipe L2, the slurry supply tank 21, and the pipe L3. A chemically strengthened glass substrate (manufactured by Corning Japan) which is 65 mmϕ is used as the polishing target and a suede cloth is used as the polishing cloth P. The pressure on the polishing surface during polishing is 9.8 kPa (100 g/cm²) and the rotating speed of the polishing tester is set to 100 min⁻¹ (rpm). While the polishing agent slurry 23 is circulated, the chemically strengthened glass substrate is replaced as necessary and polishing is performed continuously. The K₂O density of the polishing agent slurry 23 is monitored by the ion meter M provided in the slurry supply tank 21. The polishing is ended when the density reaches 0.05 mass %. This polishing treatment condition is to be a polishing treatment condition 1. Next, 100 L of polishing agent slurry 23 is transported to the slurry supply tank 21 provided in the polishing agent slurry collecting step 2 through the pipe L4.

The K₂O density is measured by performing measurement by combining the potassium ion electrode “8202-10C” and the desktop ion meter “F74” (both of the above manufactured by HORIBA, Ltd.) and performing a calculation converting to the K₂O density.

When the regenerated polishing agent slurry 1 is prepared, dilution by the dilution water W1 is not performed, and the polishing agent slurry 23 including the K₂O with the density of 0.05 mass % is transported as is to the next step which is the sedimenting/separating/concentrating step 3 through the pipe L5.

2) Sedimenting/Separating/Concentrating Step 3

After the polishing agent slurry is transported to the separating/concentrating tank 32 provided in the sedimenting/separating/concentrating step 3, the liquid temperature of the polishing agent slurry is controlled within the range of 20±1° C. While stirring to a degree that the cerium oxide is not sedimented, 2.5 liters of magnesium sulfate aqueous solution at 10 mass % is added from the additive tank using 10 minutes. The pH value at 25° C. conversion is 8.60 right after the magnesium chloride is added and this condition is maintained.

After stirring continuously for 30 minutes in this state, the above is placed still for 1.5 hours, and the above is sedimented and separated to the supernatant liquid 34 and concentrate 33 by the spontaneous sedimentation method. After 1.5 hours, the supernatant liquid 34 is discharged using a drainage pump, and the aggregate 33 is separated and collected. The aggregate 33 including the collected polishing agent particles is 20 liters.

3) Specific Gravity Adjusting Step 4

When the regenerated polishing agent slurry 1 is prepared, the adjustment of the specific gravity in the specific gravity adjusting step 4 is not performed.

4) Polishing Agent Particle Size Adjusting Step 5

When the separated concentrate 33 is transported to the polishing agent separating liquid storage tank 42, 30 liters of water is added. Further, 300 g of Mighty 21 HP (manufactured by Kao) which is an additive including a dispersion function is added as a dispersing agent by the additive tank 41. After stirring for 30 minutes, the ultrasound disperser (44) is used to disperse and release the concentrate while monitoring the particle size distribution of the polishing agent particle with the particle size measurer 45. With this, the regenerated polishing agent including the polishing agent with the predetermined particle size is obtained.

5) Regenerated Polishing Agent Slurry Preparing Step 6

The regenerated polishing agent is transported to the regenerated polishing agent slurry storage tank 51 and the density is adjusted. With this, 60 liters of the regenerated polishing agent slurry including the regenerated cerium oxide is obtained. The density of the cerium oxide is 10 mass %, the granularity is (D₉₀<2.0 μm) and the amount of magnesium included is 0.01 mass %.

[Preparation of Regenerated Polishing Agent Slurry 2]

The regenerated polishing agent slurry 2 is similarly prepared with the exception of changing the polishing treatment condition 1 in the 2) polishing treating step to the polishing treatment condition 2 described below in the above-described preparation of the regenerated polishing agent slurry 1.

(Polishing Treatment Condition 2 in Polishing Treating Step)

With the condition applied to the preparation of the regenerated polishing agent slurry 1, while the polishing agent slurry is circulated, the chemically strengthened glass substrate is exchanged as necessary and the polishing is performed continuously. The K₂O density of the polishing agent slurry is monitored with the ion meter M provided in the slurry supply tank 21. The polishing is ended when the density becomes 1.0 mass %. The polishing agent slurry is transported to the slurry supply tank 21 provided in the polishing agent slurry collecting step 2 through the pipe L4. This polishing treatment condition is to be the polishing treatment condition 2.

[Preparation of Regenerated Polishing Agent Slurry 3]

The regenerated polishing agent slurry 3 is similarly prepared with the exception of adding the dilution water according to the following method using the dilution water W1 and then performing the process of the sedimenting/separating/concentrating step as described below in the above-described polishing agent slurry collecting step used for the preparation of the regenerated polishing agent slurry 1.

(Polishing Agent Slurry Collecting Step)

In the polishing treating step, 50 L of the polishing agent slurry in which K₂O is included at 0.05 mass % is transported to the slurry supply tank 21 provided in the polishing agent slurry collecting step 2 through the pipe L4.

Next, in order to perform dilution of the polishing agent slurry by 50 times, the dilution water W1 is added to the slurry supply tank 21, and the diluted polishing agent slurry is prepared with a total amount of 2500 L and the K₂O density at 0.001 mass %.

(Sedimenting/Separating/Concentrating Step)

After transporting 2500 L of the diluted polishing agent slurry to the separating/concentrating tank 32 included in the sedimenting/separating/concentrating step 3, the liquid temperature of the diluted polishing agent slurry is controlled within the range of 20±1° C. While stirring to a degree that the cerium oxide is not sedimented, 2.5 liters of magnesium sulfate aqueous solution at 10 mass % is added from the additive tank 31 using 10 minutes. The pH value at 25° C. conversion is 8.60 right after the magnesium chloride is added and this condition is maintained.

After stirring continuously for 30 minutes in this state, the above is placed still for 1.5 hours, and the above is sedimented and separated to the supernatant liquid 34 and concentrate 33 by the spontaneous sedimentation method. After 1.5 hours, 2410 L of the supernatant liquid is discharged using a drainage pump, and the aggregate is separated and collected. The aggregate including the collected polishing agent particles is 10 L.

[Preparation of Regenerated Polishing Agent Slurry 4]

The regenerated polishing agent slurry 4 is similarly prepared with the exception of adding the dilution water according to the following method using the dilution water W1 and then performing the process of sedimenting/separating/concentrating step as described below in the above-described polishing agent slurry collecting step used for the preparation of the regenerated polishing agent slurry 2.

(Polishing Agent Slurry Collecting Step)

In the polishing treating step, 100 L of the polishing agent slurry in which K₂O is included at 1.0 mass % is transported to the slurry supply tank 21 provided in the polishing agent slurry collecting step 2 through the pipe L4.

Next, in order to perform dilution of the polishing agent slurry by 4 times, 300 L of the dilution water W1 is added to the slurry supply tank 21, and diluted polishing agent slurry is prepared with a total amount of 400 L.

(Sedimenting/Separating/Concentrating Step)

After transporting 400 L of the diluted polishing agent slurry to the separating/concentrating tank 32 included in the sedimenting/separating/concentrating step 3, the liquid temperature of the diluted polishing agent slurry is controlled within the range of 20±1° C. While stirring to a degree that the cerium oxide is not sedimented, 2.5 liters of magnesium sulfate aqueous solution at 10 mass % is added from the additive tank 31 using 10 minutes. The pH value at 25° C. conversion is 8.60 right after the magnesium chloride is added and this condition is maintained.

After stirring continuously for 30 minutes in this state, the above is placed still for 1.5 hours, and the above is sedimented and separated to the supernatant liquid 34 and concentrate 33 by the spontaneous sedimentation method. After 1.5 hours, 300 L of the supernatant liquid 34 is discharged using a drainage pump, and the aggregate is separated and collected. The aggregate including the collected polishing agent particles is 100 L.

[Preparation of Regenerated Polishing Agent Slurry 5]

The regenerated polishing agent slurry 5 is similarly prepared with the exception of setting the K₂O density of the polishing agent slurry prepared in the polishing treating step to 0.1 mass %, and changing the K₂O density of the polishing agent slurry after dilution in the polishing agent slurry collecting step to 0.002 mass % in the above-described preparation of the regenerated polishing agent slurry 3.

[Preparation of the Regenerated Polishing Agent Slurry 6]

The regenerated polishing agent slurry 6 is similarly prepared with the exception of setting the dilution magnification in the polishing agent slurry collecting step to 5 times and changing the K₂O density of the polishing agent slurry after dilution to 0.20 mass % in the above-described preparation of the regenerated polishing agent slurry 4 using the polishing agent slurry with the K₂O density being 1.0 mass %.

[Preparation of Regenerated Polishing Agent Slurry 7]

The regenerated polishing agent slurry 7 is similarly prepared with the exception of setting the dilution magnification in the polishing agent slurry collecting step to 10 times and changing the K₂O density of the polishing agent slurry after dilution to 0.01 mass % in the above-described preparation of the regenerated polishing agent slurry 5 using the polishing agent slurry with the K₂O density being 0.1 mass %.

[Preparation of Regenerated Polishing Agent Slurry 8]

The regenerated polishing agent slurry 8 is similarly prepared with the exception of setting the dilution magnification in the polishing agent slurry collecting step to 20 times and changing the K₂O density of the polishing agent slurry after dilution to 0.05 mass % in the above-described preparation of the regenerated polishing agent slurry 4 using the polishing agent slurry with the K₂O density being 1.0 mass %.

[Preparation of Regenerated Polishing Agent Slurry 9]

The regenerated polishing agent slurry 9 is similarly prepared with the exception of setting the dilution magnification in the polishing agent slurry collecting step to 100 times and changing the K₂O density of the polishing agent slurry after dilution to 0.01 mass % in the above-described preparation of the regenerated polishing agent slurry 4 using the polishing agent slurry with the K₂O density being 1.0 mass %.

[Preparation of Regenerated Polishing Agent Slurry 10]

The regenerated polishing agent slurry 10 is similarly prepared with the exception of setting the K₂O density of the polishing agent slurry prepared in the polishing treating step to be 0.5 mass % and changing the K₂O density of the polishing agent slurry after dilution in the polishing agent slurry collecting step to 0.05 mass % in the above-described preparation of the regenerated polishing agent slurry 7.

[Preparation of Regenerated Polishing Agent Slurry 11 and 12]

The regenerated polishing agent slurry 11 and 12 are similarly prepared with the exception of providing a specific gravity adjusting step 4 between the sedimenting/separating/concentrating step 3 and the polishing agent particle size adjusting step 5 in the above-described preparation of the regenerated polishing agent slurry 7 and 8.

(Specific Gravity Adjusting Step)

After the concentrate 33 is collected in the sedimenting/separating/concentrating step 3, as shown in the reference numeral 4 in FIG. 1, the ultrafiltration apparatus 37 including the membrane filter is used to discharge the unnecessary salts included in the regenerated polishing slurry outside the system. At the same time, while the added amount of the dilution water W3 and the drainage amount 36 from the ultrafiltration apparatus 37 are controlled, the specific gravity of the polishing agent slurry after the sedimentating/separating step process is matched to the specific gravity of the polishing agent slurry 21 before adding water in the polishing agent slurry supplying step 20.

The specific gravity is measured at 25° C. using a vibration type density hydrometer by ADVANTEC CO., LTD.

<Evaluation of Regenerated Polishing Agent Slurry>

[Evaluation of Separativeness in Sedimenting/Separating/Concentrating Step] The amount of glass components (Si component) in the supernatant liquid and the polishing agent slurry (mother liquid) is analyzed according to the method below using a ICP emission spectrochemical plasma analysis using the supernatant liquid 34 in the sedimenting/separating/concentrating step 3 and the polishing agent slurry (mother liquid) shown in numeral 23 in FIG. 1 as the mother liquid before sedimenting/separating in the preparation of each regenerated polishing agent slurry.

(Sampling of Polishing Agent Slurry (Mother Liquid))

Regarding the polishing agent slurry (mother liquid), in the evaluation of the regenerated polishing agent slurry 1, 3, 4, 7, 8, and 11 the polishing agent slurry with the K₂O density of 0.05 mass % prepared with the polishing treatment condition 1 is used as the mother liquid.

In the evaluation of the regenerated polishing agent slurry 2, 5, 6, 9, 10, and 12, the polishing agent slurry with the K₂O density of 1.0 mass % prepared with the polishing treatment condition 2 is used as the mother liquid.

(Preparation of Supernatant Liquid)

Regarding the supernatant liquid sampled in the sedimenting/separating/concentrating step 3, the following adjustment of the density is performed.

(1) In the preparation of the regenerated polishing agent slurry 1 and 2, the dilution in the polishing agent slurry collecting step is not performed. Therefore, the supernatant liquid sampled in the sedimenting/separating/concentrating step 3 is used as is.

(2) In the preparation of the regenerated polishing agent slurry 3, 5, 7, and 9, diluted by 5 times using the dilution water in the polishing agent slurry collecting step, the supernatant liquid sampled in the sedimenting/separating step 3 is concentrated to ⅕.

(3) In the preparation of the regenerated polishing agent slurry 4, 6, 8, and 10, diluted by 50 times using the dilution water in the polishing agent slurry collecting step, the supernatant liquid sampled in the sedimenting/separating/concentrating step 3 is concentrated to 1/50.

(4) In the preparation of the regenerated polishing agent slurry 11 and 12 diluted by 4 times using the dilution water in the polishing agent slurry collecting step, the supernatant liquid sampled in the sedimenting/separating/concentrating step 3 is concentrated to ¼.

(Component Analysis by CP Emission Spectrometry Plasma Component Analysis)

<Preparation of Sample Liquid A>

(a) 1 ml of a sample (polishing agent slurry liquid (mother liquid) and supernatant liquid) is gathered while stirring the sample with a stirrer.

(b) 5 ml of hydrofluoric acid for atomic absorption is added.

(c) Ultrasound dispersion is performed and silica is eluted.

(d) Place quietly for 30 minutes at room temperature.

(e) Ultrapure water is used so that the total amount is 50 ml.

The sample liquid prepared according to the above procedure is called the sample liquid A.

<Quantifying of Si and Mg>

(a) Each sample liquid A is filtered with a membrane filter (hydrophilic PTFE).

(b) The filtered liquid is measured with an inductively coupled plasma atomic emission spectrometry (ICP-AES, manufactured by SII NanoTechnology Inc.).

(c) Si is quantified by a calibration curve method of a standard adding method.

(Evaluation)

The evaluation of the separability is performed according to the following standards based on a Si density in the supernatant liquid and the Si density in the polishing agent slurry liquid (mother liquid) obtained from the above method.

AA: Si density in supernatant liquid is 1200 mg/L or more, ratio of Si density in supernatant liquid/Si density in mother liquid is 85% or more

BB: Si density in supernatant liquid is 1200 mg/L or more, ratio of Si density in supernatant liquid/Si density in mother liquid is 80% or more and less than 85% CC: Si density in supernatant liquid is 1100 mg/L or more and less than 1200 mg/L, ratio of Si density in supernatant liquid/Si density in mother liquid is 75% or more and less than 80%

DD: Si density in supernatant liquid is less than 1100 mg/L, ratio of Si density in supernatant liquid/Si density in mother liquid is less than 75%

[Evaluation of Polishing Speed Stability]

The polisher described in FIG. 1 is used, and the polishing target surface is polished with the polishing cloth while the prepared regenerated polishing agent slurry is supplied to the polishing target surface. The polishing agent slurry is supplied by circulation in a flow amount of 5 L/min and the polishing treatment is performed. A chemically strengthened glass substrate (Corning Japan) with a size of 65 mm is used as the polishing target, and a suede product is used as the polishing cloth. The pressure when the polishing surface is polished is to be 9.8 kPa (100 g/cm²), the rotating speed of the polishing tester is set to 100 min′ (rpm), and the polishing treatment is performed 30 minutes. The thickness before and after polishing is measured using Digimicro (MF 501) by Nikon Corporation, and the polishing speed (μm/minute) is measured by calculating the polishing amount (μm) in each minute from the difference of the thickness.

Next, the polishing treatment of 100 batches is performed with a similar method, the polishing speed of the 100th batch is measured, the decrease rate of the polishing speed at the 100th batch with relation to the polishing speed of the regenerated polishing agent slurry of the first batch as the reference is obtained using the following formula. The evaluation of the polishing speed stability is performed according to the following reference.

The decrease rate of the polishing speed={(polishing speed of first batch−polishing speed of 100th batch)/polishing speed of first batch}×100(%)

AA: Decrease rate of polishing speed is less than 10%

BB: Decrease rate of polishing speed is 10% or more and less than 20%

CC: Decrease rate of polishing speed is 20% or more and less than 30%

DD: Decrease rate of polishing speed is 30% or more

[Evaluation of Polishing Quality]

The polishing treatment is performed successively 300 times with the same method as the above-described evaluation of the polishing speed stability using the regenerated polishing agent slurry. Confirmation of whether there are scratches on the surface of the product after polishing treatment is made by sight after the 100th, 200th, and 300th treatment. The evaluation of the polishing quality is performed according to the following evaluation ranking.

AA: There are no scratches in the product after the 300th polishing treatment

BB: There are no scratches in the product after the 250th polishing treatment, there are very small polishing scratches in the product after the 300th polishing treatment, quality is good

CC: There are no scratches in the product after the 100th polishing treatment, there are small polishing scratches in the product after the 250th polishing treatment, no problem in practical use

DD: There are clear scratches in the product after the 100th polishing treatment

The result obtained according to the above is shown in Table 1.

TABLE 1

| | | | POLISHING | | | | | |
|---|---|---|---|---|---|---|---|---|
| | | DILUTION AMOUNT | AGENT | | | | | |
| REGENER- | POLISHING | WHEN DILUTION BY | SLURRY | WHETHER | | | | |
| ATED | AGENT | WATER IS PERFORMED | AFTER | THERE IS | | | | |
| POLISHING | SLURRY | IN SEDIMENTING/ | DILUTION | SPECIFIC | | POL- | | |
| AGENT | K₂O | SEPARATING/ | K₂O | GRAVITY | | ISHING | POL- | |
| SLURRY | DENSITY | CONCENTRATING STEP | DENSITY | ADJUSTING | SEPARA- | SPEED | ISHING | |
| NUMBER | [MASS %] | [MAGNIFICATION] | [MASS %] | STEP | TIVENESS | STABILITY | QUALITY | REMARKS |
| 1 | 0.05 | — | 0.05 | NO | DD | CC | CC | COMPARATIVE |
| | | | | | | | | EXAMPLE |
| 2 | 1.0 | — | 1.0 | NO | DD | CC | CC | COMPARATIVE |
| | | | | | | | | EXAMPLE |
| 3 | 0.05 | 50 | 0.001 | NO | BB | CC | CC | COMPARATIVE |
| | | | | | | | | EXAMPLE |
| 4 | 1.0 | 4 | 0.25 | NO | CC | CC | CC | COMPARATIVE |
| | | | | | | | | EXAMPLE |
| 5 | 0.1 | 50 | 0.002 | NO | BB | BB | BB | PRESENT |
| | | | | | | | | INVENTION |
| 6 | 1.0 | 5 | 0.20 | NO | BB | BB | BB | PRESENT |
| | | | | | | | | INVENTION |
| 7 | 0.1 | 10 | 0.01 | NO | AA | BB | AA | PRESENT |
| | | | | | | | | INVENTION |
| 8 | 1.0 | 20 | 0.05 | NO | AA | BB | AA | PRESENT |
| | | | | | | | | INVENTION |
| 9 | 1.0 | 100 | 0.01 | NO | BB | BB | BB | PRESENT |
| | | | | | | | | INVENTION |
| 10 | 0.5 | 10 | 0.05 | NO | AA | AA | BB | PRESENT |
| | | | | | | | | INVENTION |
| 11 | 0.1 | 10 | 0.01 | YES | AA | AA | AA | PRESENT |
| | | | | | | | | INVENTION |
| 12 | 1.0 | 20 | 0.05 | YES | AA | AA | AA | PRESENT |
| | | | | | | | | INVENTION |

According to the regenerating method of the polishing agent of the present invention, in a regenerating method of a polishing agent using chemically strengthened glass as a glass substrate, the K₂O density in the polishing agent slurry collected after the polishing process is measured, and after the dilution is performed according to the measured result within the range of 5 to 50 times, the sedimentation separation operation is performed. As clearly shown in the result described in table 1, according to such regenerating method, compared to the comparative example, excellent results are achieved regarding the separativeness of the glass components, stability of the polishing speed, and the polishing quality after polishing.

### INDUSTRIAL APPLICABILITY

The regenerating method of the polishing agent according to the present invention is a regenerating method of the polishing agent which achieves stability in the polishing speed and which prevents the quality from decreasing due to scratches, etc. caused by polishing scrap, etc. The regenerating method of the polishing agent according to the present invention can be suitably applied to the regenerating method of the polishing agent in which the polishing agent slurry used in polishing of chemically strengthened glass is treated and the glass components including K₂O is efficiently removed.

### REFERENCE SIGNS LIST

1 polishing treating step
2 polishing agent slurry collecting step
3 sedimenting/separating/concentrating step
4 specific gravity adjusting step
5 polishing agent particle size adjusting step
6 regenerated polishing agent slurry adjusting step
11 washing water tank
12 polisher
20 polishing agent slurry supplying step
21 slurry supply tank
22 collected mixed liquid tank
23 polishing agent slurry
24 diluted polishing agent slurry
31 additive tank
32 separation/concentration tank
33 concentrate
34 supernatant liquid
35 discharge
36 drainage amount
37 ultrafiltration apparatus
41 additive tank
42 polishing agent separation liquid storage tank
44 ultrasound disperser
45 particle size measurer
51 regenerated polishing agent slurry storage tank
A polishing plate
B polished material (chemically strengthened glass)
C polished material holder
F pressure
L1-L12 pipe
M ion meter
P polishing cloth
W1, W2, W3 dilution water

1. A polishing agent regenerating method in which a component of a polished material is removed from polishing agent slurry and a polishing agent is collected and regenerated, the method comprising:
at least, polishing, polishing agent slurry supplying, polishing agent slurry collecting, and sedimenting/separating/concentrating, performed in the above order,
wherein, in the polishing agent slurry collecting or the sedimenting/separating/concentrating, a K₂O density in the polishing agent slurry after dilution by water is performed is to be within a range of 0.002-0.2 mass %.

2. The polishing agent regenerating method according to claim 1, wherein, in the polishing agent slurry collecting or the sedimenting/separating/concentrating, a K₂O density in the polishing agent slurry after dilution by water is to be within a range of 0.01-0.05 mass %.

3. The polishing agent regenerating method according to claim 1 or 2, wherein, in the polishing agent slurry supplying, the polishing agent slurry with a K₂O density within a range of 0.1-1.0 mass % is used.

4. The polishing agent regenerating method according to claim 1, further comprising specific gravity adjusting in which specific gravity of the polishing agent slurry after the sedimenting/separating/concentrating is matched to specific gravity of the polishing agent slurry before adding water in the polishing agent slurry supplying.

5. The polishing agent regenerating method according to claim 4, further comprising adjusting a particle size of the polishing agent after the specific gravity adjusting.

6. The polishing agent regenerating method according to claim 1, further comprising, between the polishing and the sedimenting/separating/concentrating, a K₂O density measurer which automatically measures the K₂O density in the polishing agent slurry and a water adder which automatically adds an added amount of water for dilution according to the obtained K₂O density information.

7. The polishing agent regenerating method according to claim 1, wherein, the polished material is chemically strengthened glass.

8. A polishing agent recycle processing system in which a component of a polished material is removed from polishing agent slurry and a polishing agent is collected and regenerated, the system comprising:
a polisher;
a polishing agent slurry supplier which includes a slurry supply tank which supplies the polishing agent slurry to the polisher;
a polishing agent slurry collector which includes a collected mixed liquid tank in which mixed liquid including treated polishing agent slurry and washing water are mixed is stored;
a sedimentor/separator/concentrator which includes a separating tank which separates the mixed liquid to a transparent liquid and a concentrated liquid of the polishing agent; and
a water adder in which in the polishing agent slurry collector or the sedimentor/separator/concentrator, a K₂O density in the polishing agent slurry after dilution by water is to be within a range of 0.002-0.2 mass %.

9. The polishing agent recycle processing system according to claim 8, wherein, in the water adder, a K₂O density in the polishing agent slurry after dilution by water is to be within a range of 0.01-0.05 mass %.

10. The polishing agent recycle processing system according to claim 8, wherein, in the polishing agent slurry supplier, the polishing agent slurry with a K₂O density within a range of 0.1-1.0 mass % is used.

11. The polishing agent recycle processing system according to claim 8, further comprising a specific gravity adjuster in which specific gravity of the polishing agent slurry after the sedimenting/separating/concentrating is matched to specific gravity of the polishing agent slurry before adding water in the polishing agent slurry supplying.

12. The polishing agent recycle processing system according to claim 11, further comprising an adjustor which adjusts a particle size of the polishing agent obtained by the specific gravity adjuster.

13. The polishing agent recycle processing system according to claim 8, further comprising, between the polisher and the sedimentor/separator/concentrator, a K₂O density measurer which automatically measures the K₂O density in the polishing agent slurry and a water adder which automatically adds an added amount of water for dilution according to the obtained K₂O density information.
